(19) United States
(12) Patent Application Publication
(10) Pub. No.: US 2026/0348016 A1
(43) Pub. Date: Nov. 5, 2026

(54) SUBSTRATE ALIGNMENT ASSEMBLY FOR DUAL CHAMBER PROCESS MODULES

(71) Applicant: ASM IP Holding B.V., Almere (NL)

(72) Inventors: Partha Sarathy Reddy Kudala, Tempe, AZ (US); Fan Gao, Chandler, AZ (US); Kishor Patil, Chandler, AZ (US); Han Ye, Phoenix, AZ (US); Yue Zhao, Chandler, AZ (US); Junwei Su, Chandler, AZ (US); Rohan Kota, Phoenix, AZ (US)

(21) Appl. No.: 19/658,828

(22) Filed: Apr. 27, 2026

Related U.S. Application Data
(60) Provisional application No. 63/797,522, filed on Apr. 30, 2025.

(51) Int. Cl. C23C 16/458; C30B 25/08; C30B 25/12; H10P 72/00; H10P 72/50; H10P 72/76

(52) U.S. Cl. CPC C23C 16/4583; C30B 25/08; C30B 25/12; H10P 72/0454; H10P 72/50; H10P 72/7602

(57) ABSTRACT

A substrate alignment assembly in a semiconductor processing system is disclosed in order to independently adjust the planar orientations of substrates in a dual chamber process module. The substrate alignment assembly, in cooperation with a main lift driver, can provide for more accurate positioning of the substrates in the dual chamber process module.

### CROSS-REFERENCE TO RELATED APPLICATIONS

This application is a nonprovisional of, and claims priority to and the benefit of, U.S. Provisional Patent Application No. 63/797,522, filed Apr. 30, 2025 and entitled “SUBSTRATE ALIGNMENT ASSEMBLY FOR DUAL CHAMBER PROCESS MODULES,” which is hereby incorporated by reference herein.

### FIELD

The present disclosure relates generally to the field of semiconductor processing methods and systems and to the field of device and integrated circuit manufacture. More particularly, the present disclosure generally relates to a substrate adjustment component of the semiconductor processing system to allow for precise positioning of substrates within different reaction chambers of the semiconductor processing system.

### BACKGROUND

Any discussion, including discussion of problems and solutions set forth in this section, has been included in this disclosure solely for the purpose of providing a context for the present disclosure, and should not be taken as an admission that any or all of the discussion was known at the time the invention was made or otherwise constitutes prior art.

A semiconductor processing system may comprise one or more dual chamber process modules. In each dual chamber process module, two independent processing chambers may be housed within a single system frame or platform. Each processing chamber may perform the same or different process steps, such as etching, deposition, or cleaning. For example, if one of the process chambers is performing etching, the other processing chamber may perform deposition. The two processing chambers can process wafers simultaneously, almost doubling the productivity compared to a single chamber process module.

The two processing chambers of a dual chamber process module may include different components for processing substrates in the process chambers, such as a gas supply unit, a substrate support unit, an exhaust unit, and other accessory components. In order to maintain smooth substrate handling and stable process results, the substrates may need to be properly placed in designated locations within the processing chambers. For example, a substrate in one of the two processing chambers of the dual chamber process module performing deposition may need to be positioned correctly in the processing chamber such that the flat, circular surface of the substrate is parallel to the gas supply unit disposed above the substrate. Otherwise, the uniformity of a thin film deposited on the substrate may be reduced.

Furthermore, in a high-temperature process, the components within the processing chambers may be dislocated from the designated locations within the process chamber or may be out of alignment with each other due to thermal expansion or vacuum force applied to the processing chambers. For example, thermal deformation of a reactor lid, including a gas supply unit, may cause a distance between the gas supply unit and a substrate being supported by a susceptor. In the cases described, the substrates being supported by the susceptors may need to be realigned. The alignment may allow for horizontal centering of a substrate within the processing chamber.

Furthermore, the two processing chambers in the dual chamber may be performing two different processes at different temperatures, pressure levels, and/or vacuum levels. Therefore, the alignment needed for a substrate in one of the processing chambers may be different from the alignment needed for another substrate in the other processing chamber. Therefore, there is a need for a mechanism in a dual chamber process module for independent alignment of substrates inside the two process chambers.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to proper positioning and/or alignment of substrates in a dual chamber process module.

In accordance with examples of the disclosure, a semiconductor processing system described herein may comprise a first susceptor in a first process chamber of a dual chamber process module, where the first susceptor may be configured to hold a first substrate. The semiconductor processing system further may comprise a second susceptor in a second process chamber of the dual chamber process module, where the second susceptor may be configured to hold a second substrate. The semiconductor processing system may further comprise a substrate alignment assembly configured to cause a first adjustment of a first planar orientation of the first susceptor and a second adjustment of a second planar orientation of the second susceptor, where the first adjustment is independent of the second adjustment.

In accordance with examples of the disclosure, the substrate alignment assembly may comprise a first alignment plate coupled to the first susceptor and a second alignment plate coupled to the second susceptor. Each of the first alignment plate and the second alignment plate may comprise a first side and a second side parallel to the first side. A first tilting of the first alignment plate may cause a first corresponding tilting in the first susceptor, and a second tilting of the second alignment plate may cause a second corresponding tilting in the second susceptor.

In accordance with examples of the disclosure, the substrate alignment assembly may further comprise a first tilting unit configured to tilt the first susceptor around a first planar axis by tilting the first side of the first alignment plate and a second tilting unit configured to tilt the second susceptor around the first planar axis by tilting the first side of the second alignment plate.

In accordance with examples of the disclosure, each of the first tilting unit and the second tilting unit may comprise a wedge and an adjustment mechanism coupled to the wedge. Turning the adjustment mechanism of the first tilting unit in a first direction may drive the wedge of the first tilting unit under the first side of the first alignment plate and tilt the first side of the first alignment plate upward. Turning the adjustment mechanism of the first tilting unit in a second direction may remove the wedge of the first tilting unit from under the first side of the first alignment plate and tilt the first side of the first alignment plate downward. Turning the adjustment mechanism of the second tilting unit in the first direction may drive the wedge of the second tilting unit under the first side of the second alignment plate and tilt the first side of the second alignment plate upward. Turning the adjustment mechanism of the second tilting unit in the second direction may remove the wedge of the second tilting unit from under the first side of the second alignment plate and tilt the first side of the second alignment plate downward.

In accordance with examples of the disclosure, the substrate alignment assembly may further comprise a fastener coupling the adjustment mechanism of the first tilting unit and the adjustment mechanism of the second tilting unit.

In accordance with examples of the disclosure, the stem of the adjustment mechanism of the first tilting unit may be parallel to the stem of the adjustment mechanism of the second tilting unit.

In accordance with examples of the disclosure, each of the first alignment plate and the second alignment plate may comprise a trapezoid shape.

In accordance with examples of the disclosure, the substrate alignment assembly may further comprise a third tilting unit configured to tilt the first susceptor around a second axis by tilting a first corner of the second side of the first alignment plate and a fourth tilting unit configured to tilt the second susceptor around the second axis by tilting a first corner of the second side of the second alignment plate.

In accordance with examples of the disclosure, each of the third tilting unit and the fourth tilting unit comprises a wedge and an adjustment mechanism coupled to the wedge. Turning the adjustment mechanism of the third tilting unit in a first direction may drive the wedge of the third tilting unit under the first corner of the second side of the first alignment plate and tilt the first corner of the second side of the first alignment plate upward. Turning the adjustment mechanism of the third tilting unit in a second direction may remove the wedge of the third tilting unit from under the first corner of the second side of the first alignment plate and tilt the first corner of the second side of the first alignment plate downward. Turning the adjustment mechanism of the fourth tilting unit in the first direction may drive the wedge of the fourth tilting unit under the first corner of the second side of the second alignment plate and tilt the first corner of the second side of the second alignment plate upward. Turning the adjustment mechanism of the third tilting unit in the second direction may remove the wedge of the fourth tilting unit from under the first corner of the second side of the second alignment plate and tilt the first corner of the second side of the second alignment plate downward.

In accordance with examples of the disclosure, the substrate alignment assembly may further comprise a fifth tilting unit configured to tilt the first susceptor around the second axis by tilting a second corner of the second side of the first alignment plate and a sixth tilting unit configured to tilt the second susceptor around the second axis by tilting a second corner of the second side of the second alignment plate.

In accordance with examples of the disclosure, each of the fifth tilting unit and the sixth tilting unit may comprise a second wedge and a second adjustment mechanism coupled to the second wedge. Turning the second adjustment mechanism of the fifth tilting unit in the first direction may drive the second wedge of the fifth tilting unit under the second corner of the second side of the first alignment plate and tilt the second corner of the second side of the first alignment plate upward. Turning the second adjustment mechanism of the fifth tilting unit in the second direction may remove the second wedge of the fifth tilting unit from under the second corner of the second side of the first alignment plate and tilt the second corner of the second side of the first alignment plate downward. Turning the second adjustment mechanism of the sixth tilting unit in the first direction may drive the second wedge of the fourth tilting unit under the second corner of the second side of the second alignment plate and tilt the second corner of the second side of the second alignment plate upward. Turning the second adjustment mechanism of the sixth tilting unit in the second direction may remove the wedge of the sixth tilting unit from under the second corner of the second side of the second alignment plate and tilt the second corner of the second side of the second alignment plate downward.

In accordance with examples of the disclosure, a stem of the adjustment mechanism of the third tilting unit may be parallel to a stem of the second adjustment mechanism of the fifth tilting unit. A stem of the adjustment mechanism of the fourth tilting unit may be parallel to the stem of the second adjustment mechanism of the sixth tilting unit.

In accordance with examples of the disclosure, the substrate alignment assembly may comprise a first shifting plate coupled to the first alignment plate and a second shifting plate coupled to the first shifting plate. A first shifting of the first shifting plate may cause a first corresponding shifting in the first susceptor along a first axis. A second shifting of the second alignment plate may cause a second corresponding shifting in the first susceptor along a second axis. The first shifting of the first shifting plate or the second shifting of the second shifting plate does not change the first planar orientation of the first susceptor.

In accordance with examples of the disclosure, the substrate alignment assembly may further comprise a first shifting unit coupled to the first shifting plate and comprising a first adjustment mechanism. Turning the first adjustment mechanism may cause the first susceptor to shift along the first axis.

In accordance with examples of the disclosure, the substrate alignment assembly may further comprise a second shifting unit coupled to the second shifting plate and comprising a second adjustment mechanism. Turning the second adjustment mechanism may cause the first susceptor to shift along the second axis.

In accordance with examples of the disclosure, the substrate alignment assembly may further comprise a third shifting plate coupled to the second alignment plate and a fourth shifting plate coupled to the third shifting plate. A third shifting of the third shifting plate may cause a third corresponding shifting in the second susceptor along the first axis, and a fourth shifting of the fourth shifting plate may cause a fourth corresponding shifting in the second susceptor along the second axis.

In accordance with examples of the disclosure, the substrate alignment assembly may further comprise a third shifting unit coupled to the third shifting plate and comprising a third adjustment mechanism. Turning the third adjustment mechanism may cause the second susceptor to shift along the first axis.

In accordance with examples of the disclosure, the substrate alignment assembly may further comprise a fourth shifting unit coupled to the fourth shifting plate and comprising a fourth adjustment mechanism. Turning the fourth adjustment mechanism may cause the second susceptor to shift along the second axis.

In accordance with examples of the disclosure, the first adjustment or the second adjustment may be performed by a human operator or a programmable robot.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 is a schematic view of a semiconductor processing system, including a dual chamber process module in accordance with one or more embodiments of the disclosure.

FIG. 2 illustrates a semiconductor processing system in a cluster configuration having dual chamber process modules in accordance with one or more embodiments of the disclosure.

FIG. 3 illustrates a cross-sectional schematic of a dual chamber process module in accordance with one or more embodiments of the disclosure.

FIGS. 4A, 4B, and 4C illustrate an example substrate alignment assembly in accordance with one or more embodiments of the disclosure.

FIGS. 5A, 5B, and 5C illustrate example alignments of a substrate in a first process chamber in accordance with one or more embodiments of the disclosure.

FIGS. 6A, 6B, and 6C illustrate example alignments of another substrate in a second process chamber in accordance with one or more embodiments of the disclosure.

FIGS. 7A, 7B, 7C, 7D, 7E, and 7F illustrate further alignments of a substrate in a first process chamber with one or more embodiments of the disclosure.

FIGS. 8A, 8B, 8C, 8D, 8E, and 8F illustrate further alignments of another substrate in a second process chamber with one or more embodiments of the disclosure.

FIG. 9 illustrates an example method of aligning substrates in a dual chamber process module in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, the recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous, rigid, or flexible, solid, or porous. The “substrate” may be in any form, such as a powder, a plate, or a workpiece. Substrates in the form of a plate may include wafers in various shapes and sizes. Substrates may be made from materials, such as silicon, silicon germanium, silicon oxide, gallium arsenide, gallium nitride, and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system, allowing for the manufacture and output of the continuous substrate in any appropriate form. Non-limiting examples of a continuous substrate may include a sheet, a non-woven film, a roll, a foil, a web, a flexible material, or a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forms about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to an average, median, representative, majority, etc., in some embodiments. Further, in this disclosure, the terms “including,” “constituted by,” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure; it should be noted that the chemical formulas given for each of the example materials should not be construed as limiting and that the non-limiting example materials given should not be limited by a given example stoichiometry.

In the specification, it will be understood that the terms “on” or “over” may be used to describe a relative location relationship. Another element, film, or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood that the terms “under,” “underlying,” or “below” will be construed to be relative concepts.

As used herein, the term “planar orientation” of a substrate can refer to the direction in which the flat, circular surface of the substrate is oriented in three-dimensional space. Since the substrate may be disposed on a flat surface of a susceptor, the planar orientation of the substrate may be typically described by the planar orientation of the susceptor. The planar orientation of a substrate may be represented relative to a global coordinate system (e.g., the cartesian coordinate system). For example, the center of the flat, circular surface of a substrate may be at the intersection of the x, y, and z axes of the global coordinate system, and the surface may be parallel to the x-y plane.

As used herein, the term “tilting” of a substrate can refer to changing the planar orientation of the substrate, which is equivalent to rotating the substrate relative to the x and y axes. As used herein, the term “shifting” of a substrate can refer to moving its center point to a different location without changing its planar orientation.

Various embodiments of the present disclosure relate to process modules, including first and second process chambers. The process modules may be configured for concurrent epitaxial deposition of material layers within the first and second process chambers. Semiconductor processing systems, including such process modules, as well as epitaxial deposition methods for forming epitaxial material layers employing the process modules, are also disclosed.

Commonly employed semiconductor processing systems can have a limited throughput of substrates through the system for certain deposition techniques. The limited throughput of substrates through the semiconductor processing systems may be due to a number of factors including, but not limited to, the number of substrate supports per unit area occupied by the semiconductor processing system (e.g., in a cluster-type platform). The limitation of the number of substrate supports per unit area in a semiconductor processing system can have a particular impact on substrate throughput when deposition processes are performed for extended time periods (e.g., beyond 60 minutes or more).

Certain semiconductor processing systems, such as atomic layer deposition (ALD) systems, for example, have looked to improve substrate throughput through the use of process modules, including two or more metal chambers. However, process modules, including multiple metal chambers, may not be utilized or directly adapted for epitaxial deposition processes performed at high deposition temperatures. In such high-temperature processes, a reaction chamber formed from a quartz assembly, which is transparent to heating lamps disposed above and/or below the quartz assembly, may be utilized.

According to various embodiments of the present disclosure, process modules that include two quartz assemblies may be provided within a common housing. Such process modules (referred to herein as dual chamber process modules) can increase the number of substrate supports per unit area for high-temperature epitaxial deposition process and, therefore, increase the throughput of the semiconductor processing system (e.g., cluster-type platforms), including such dual chamber process modules.

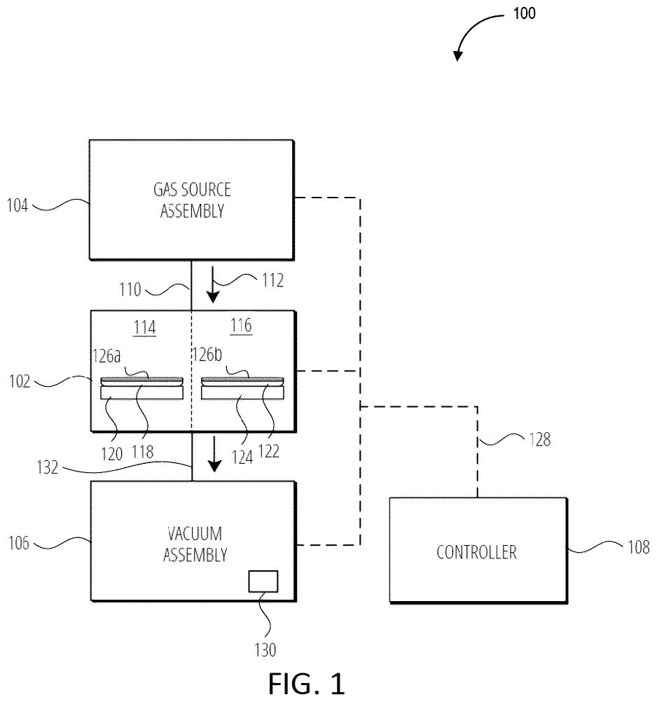

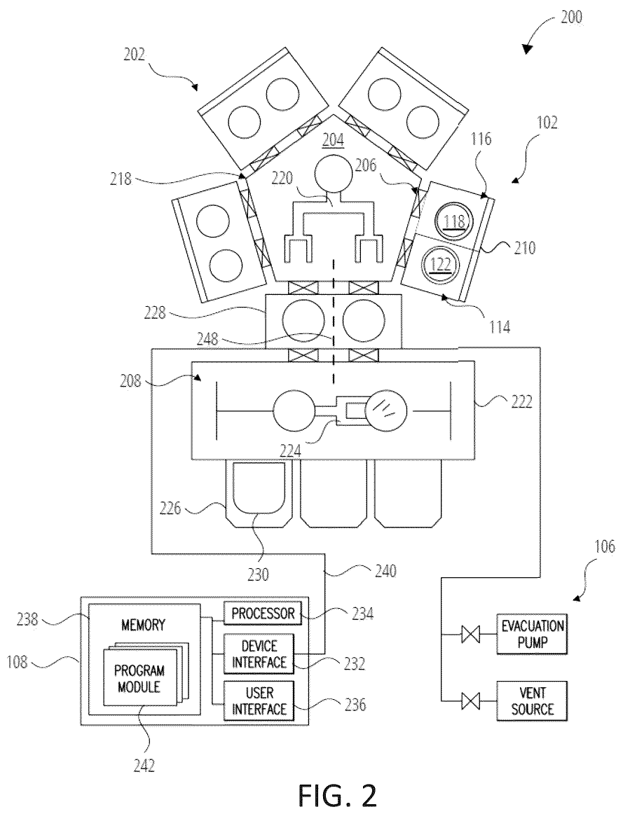

For purposes of explanation and illustration, and not limitation, exemplary semiconductor processing systems, including a dual chamber process module, are illustrated in FIG. 1 and FIG. 2. The systems and methods of the present disclosure may be used for the epitaxial deposition of material layers, such as epitaxial silicon-containing layers, with increased throughput and efficiency by employing dual chamber process modules configured to perform parallel epitaxial CVD processes. As will be appreciated by those of skill in the art in view of the present disclosure, semiconductor processing systems (including dual chamber process module) configured for other material layer deposition operations (e.g., atomic layer deposition, plasma-enhanced deposition, and the like) as well as semiconductor processing systems configured for processing operations other than epitaxial material layer deposition can also benefit from the present disclosure.

FIG. 1 illustrates a schematic view of a semiconductor processing system 100, including a process module 102. The semiconductor processing system 100 may further comprise a gas source assembly 104, a vacuum assembly 106, and/or a controller 108. The gas source assembly 104 may be connected to the process module 102 by a precursor supply conduit 110 and may be configured to provide a flow of a process gas 112 to the process module 102.

The process module 102 may comprise two independent chamber arrangements, the first chamber arrangement 114 and the second chamber arrangement 116. The first chamber arrangement 114 and the second chamber arrangement 116 may comprise isolated and discrete process chambers having independent and isolated interior process volumes in terms of at least gas communication, temperature control, and vacuum levels therein, as described in detail below. The process module 102 may be configured to expose a first substrate 118, supported on a first susceptor 120, to the process gas 112. The process module 102 may also be configured to independently expose the second substrate 122, supported on the second susceptor 124, to the process gas 112. The gas source assembly 104 may be configured to independently control the flow parameters of the process gas 112 over the first substrate 118 and the second substrate 122. In certain examples, the first substrate 118 and the second substrate 122 may be exposed to the process gas 112 under environmental conditions (e.g., temperature, pressure, and the like) selected to cause epitaxial material layers 126a and 126b to be independently deposited onto the first substrate 118 and the second substrate 122.

In some embodiments, the process gas 112 may be supplied to the process module 102 by the gas source assembly 104 and may include one or more silicon-containing precursors. Examples of suitable silicon-containing precursors may include non-halogenated silicon-containing material layer precursors, such as silane (SiH₄) and disilane (Si₂H₆), and halogenated silicon-containing material layer precursors, such as dichlorosilane (H₂SiCl₂) and trichlorosilane (HCl₃Si). In accordance with certain examples, the process gas 112 may include an alloying constituent, such as a germanium-containing material layer precursor such as germane (GeH₄), a gallium-containing material layer precursor such as triethylgallium Ga(C₂H₅)₃, or an indium-containing material layer precursor such as trimethylindium ((CH₃)₃In). It is contemplated that, in certain examples, the process gas 112 may include one or more dopant-containing material layer precursors. Examples of suitable dopant-containing material layer precursors include p-type dopants like boron (B) as well as n-type dopants such as phosphorus (P), arsenic (As), and antimony (Sb). It is contemplated that, in accordance with certain examples, the process gas 112 may be co-flowed with a diluent/carrier gas, such as hydrogen (H2) gas or nitrogen (N2) gas, and/or with an etchant, such as hydrochloric (HCl) acid or chlorine (Cl2) gas.

The vacuum assembly 106 may be connected to the process module 102 by an exhaust conduit 132, which may be fluidly coupled to an external environment outside of the semiconductor processing system 100 (e.g., through a vacuum pump 130 and/or an abatement device, such as a scrubber, for example). The vacuum assembly 106 (along with a process module exhaust assembly) may be configured to independently communicate a flow of residual precursor/reactant and/or any reaction byproducts to the external environment from the first chamber arrangement 114 and the second chamber arrangement 116.

It is contemplated that the controller 108 may be operably connected to one or more of the gas source assembly 104, the process module 102, and the vacuum assembly 106 to control the deposition of the material layers (e.g., 126a and 126b) onto the substrates 118 and 122. In this respect, the controller 108 may be connected to one or more of the gas source assembly 104, the process module 102, and the vacuum assembly 106 by a wired or wireless link 128 to control at least the temperature of the substrates (118, 122), the pressure within the first chamber arrangement 114 and the second chamber arrangement 116, and the flow of the process gas 112 to the first chamber arrangement 114 and the second chamber arrangement 116. Temperature of the substrates (118, 122) may be controlled, for example, using heater elements and/or temperature sensors included in the process module 102 and operatively associated and/or in communication with the controller 108. Pressure within the first chamber arrangement 114 and the second chamber arrangement 116 may be controlled using the vacuum pump 130 in fluid communication with the process module 102 by means of exhaust conduit 132.

FIG. 2 illustrates a further exemplary semiconductor processing system 200. Semiconductor processing system 200 may comprise a cluster-type platform 202 comprising two or more process modules, including at least one process module 102 in accordance with one or more embodiments. In more detail, the semiconductor processing system 200 may include the exemplary process module 102, a back-end transfer module 204, and/or a gate valve assembly 206. The process module 102 may be coupled to the back-end transfer module 204 by the gate valve assembly 206. The semiconductor processing system 200 may also include an equipment front-end module 208, a controller 108, and a vacuum assembly 106.

In the illustrated example of FIG. 2, the semiconductor processing system 200 may include four (4) process modules, wherein one or more of the process modules includes a dual chamber process module. In certain examples, the process module 102 may comprise a first chamber arrangement 114, including a first process chamber (not illustrated), and a second chamber arrangement 116, including a second process chamber (not illustrated). The first and second process chambers are described in detail below. Each chamber arrangement 114 and 116 of the process module 102 may include heaters configured to heat a first substrate 118 independently and a second substrate 122, as described in detail below. In certain examples, the first chamber arrangement 114 and the second chamber arrangement 116 may be configured to perform a parallel deposition process. In some embodiments, deposition processes may be performed concurrently within the first chamber arrangement 114 and the second chamber arrangement 116. In some embodiments, deposition processes may be performed simultaneously within the first chamber arrangement 114 and the second chamber arrangement 116.

In other examples, the cluster-type platform 202 may include, in addition to one or more dual chamber process modules, one or more single chamber process modules, and/or one or more quad chamber modules having four (4) chamber arrangements. For example, each process module can be configured to deposit epitaxial material layers. For example, process module 102 of FIG. 2 can be configured to deposit an epitaxial layer onto a first substrate 118 and a second substrate 122 using chemical vapor deposition (CVD) techniques. In certain examples, the first chamber arrangement 114 and the second chamber arrangement 116 can comprise isolated and discrete chambers in terms of gas communication therebetween. The first chamber arrangement 114 and the second chamber arrangement 116 can be configured to perform parallel deposition processes. In some embodiments, deposition processes may be performed concurrently within the first chamber arrangement 114 and the second chamber arrangement 116. In some embodiments, deposition processes may be performed simultaneously within the first chamber arrangement 114 and the second chamber arrangement 116.

A process gas source 210 may be fluidly coupled to the first chamber arrangement 114 and the second chamber arrangement 116 (e.g., via a gas source assembly 104) and may be configured to independently provide a process gas to the chamber arrangements and their associated process chambers. The gate valve assembly 206 may couple the process module 102 to the back-end transfer module 204 and may be configured to provide selective communication between the process module 102 and the back-end transfer module 204. In this respect, it is contemplated that the gate valve assembly 206 may be configured to permit the transfer of the substrates (e.g., 118 and 122) between the back-end transfer module 204 and the process module 102 before and after deposition of an epitaxial material layer onto the substrates.

In accordance with certain examples, the gate valve assembly 206 may include a first process module gate valve. The process module 102 may include a second process module gate valve also coupling the process module 102 to the back-end transfer module 204. It is contemplated that, in certain examples, the process gas source 210 may include a reactant or a precursor suitable for deposition of a material layer, such as using a CVD deposition technique (or ALD, and/or etch processes, and the like). It is also contemplated that, in accordance with certain examples, one or more process modules of semiconductor processing system 200 may include a plasma unit configured to provide a reactant to the substrates as a plasma suitable. In this respect, one or more of the process modules of semiconductor processing system 200 can be configured to deposit a material layer onto the substrates using a PEALD or a PECVD technique by way of example.

The back-end transfer module 204 may include a back-end process chamber 218 and a back-end substrate transfer robot 220. The back-end process chamber 218 is arranged along a transfer axis 248. It is contemplated that the back-end substrate transfer robot 220 be arranged within an interior of the back-end process chamber 218 and supported within the back-end process chamber 218 for movement relative to the back-end process chamber 218 for transfer of substrates, e.g., the first substrate 118 and the second substrate 122, between the gate valve assembly 206 and the process module 102. In certain examples, the back-end process chamber 218 may have a polygonal shape. In this respect, the back-end process chamber 218 may have five sides, fewer than five sides (e.g., a rectangular or square shape), or more than five sides (e.g., a hexagonal shape), and may have the shape of a regular polygon or an irregular polygon.

The equipment front-end module 208 may be coupled to the load lock arrangement 228 and may include an enclosure 222, a front-end substrate transfer robot 224, and one or more load port 226. The enclosure 222 may house the front-end substrate transfer robot 224. The front-end substrate transfer robot 224 may be within the enclosure 222 for movement relative to the enclosure 222 for the transfer of substrates between one or more load ports 226 and the load lock arrangement 228. The one or more load ports 226 may be connected to the enclosure 222 and are configured to seat there a pod 230 housing one or more substrates prior to and subsequent to deposition of material layers, onto the substrates. In certain examples, the pod 230 may include a standard mechanical interface pod. In accordance with certain examples, the pod 230 may include a front-opening unified pod. Although shown and described herein as having three (3) load ports it is to be understood and appreciated that equipment front-end module 208 may include fewer or additional load ports and remain within the scope of the present disclosure.

The controller 108 may be operably connected to the semiconductor processing system 200 and includes a device interface 232, a processor 234, a user interface 236, and a memory 238. The device interface 232 may couple the processor 234 to the semiconductor processing system 200, for example, through (or over) a wired or wireless link 240. The processor 234 may be operably connected to the user interface 236 and may be disposed in communication with the memory 238. The memory 238 may include a non-transitory machine-readable medium having a plurality of program modules 242 recorded thereon containing instructions that, when read by the processor 234, cause the processor to execute certain operations. Among the operations are operations of a material layer deposition method, as described below.

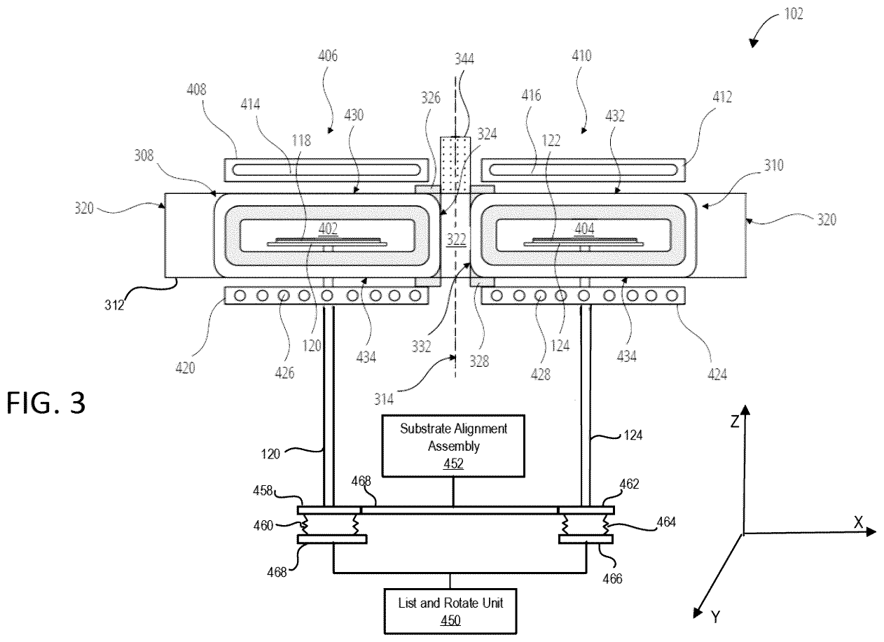

As previously described, the semiconductor processing systems 100 and 200 (FIG. 1 and FIG. 2, respectively) may include one or more dual chamber process modules comprising independently controllable first and second chamber arrangements, each chamber arrangement including an associated process chamber, i.e., a first process chamber and a second process chamber. Exemplary dual chamber process modules of the disclosure are illustrated and described in greater detail with reference to FIG. 3. In various embodiments, a process module 102 is disclosed. The process module 102 may include a first process chamber 308 and a second process chamber 310 and may be referred to as a dual chamber process module. In some embodiments, the process module 102 can be configured for performing epitaxial deposition of material layers. In some examples, the process module 102 may be configured for performing epitaxial deposition of silicon-containing layers. In certain examples, the process module 102 may be configured for performing dual epitaxial deposition of silicon-containing layers within the first process chamber 308 and the second process chamber, either concurrently or simultaneously, thereby increasing the throughput of a semiconductor processing system (e.g., the semiconductor processing system 100 or 200) comprising the dual chamber process module 102.

As illustrated in FIG. 3, the process module 102 includes a common chamber housing 312. The common chamber housing 312 has a central plane 314 that bisects the common chamber housing 312. In some embodiments, the common chamber housing 312 can comprise a sleeve housing including one or more housing side walls 320, which allow unobstructed transmission of radiation from one or more heater arrays, as described below.

In various embodiments, the first process chamber 308 and the second process chamber 310 may be disposed in a common chamber housing 312. In certain examples, the first process chamber 308 may be positioned in the common chamber housing 312 on a first side (e.g., the left side) of the central plane 314, and the second process chamber 310 may be positioned within the common chamber housing 312 on a second side (e.g., the right side) of the central plane 314. In certain examples, the first process chamber 308 and the second process chamber 310 may be mirror images of one another about the central plane 314. In such examples, the first process chamber 308 and the second process chamber 310 may be laterally positioned adjacent to one another on either side of the central plane 314.

In various embodiments, the first process chamber 308 may include a chamber interior comprising a first process volume 402, and the second process chamber 310 may include a chamber interior comprising a second process volume 404, as illustrated in FIG. 3. The first process volume 402 may encompass the first substrate 118 supported on the first susceptor 120 and the second process volume 404 may encompass the second substrate 122 supported on the second susceptor 124. In various embodiments, the first process volume 402 and the second process volume 404 may be independently controlled (e.g., in terms of temperature, process, and incoming gas flow, for example) to enable independent deposition processes to be performed concurrently upon the first substrate 118 and the second substrate 122. For example, at least the temperature, the incoming flow of process gas, and the pressure within the first process volume 402 and the second process volume 404 may be independently controlled to enable autonomous deposition processes to be performed concurrently within the first and second process chambers.

Independent temperature control of the first process volume 402 and the second process volume 404 may be realized by a number of aspects of the present disclosure. In one aspect, independent temperature control between the first process volume 402 and the second process volume 404 can be realized at least in part by utilizing independent heater arrays for the first process chamber 308 and the second process chamber 310.

In more detail, FIG. 3 illustrates aspects of independent heater arrays for the first process chamber 308 and the second process chamber 310, which in turn allows, at least in part, independent temperature control of the first process volume 402 and the second process volume 404, respectively. The process module 102 may include a first upper heater array 406 positioned above the first upper wall 430 of the first process chamber 308 and may comprise a first lamp housing 408 in which a first plurality of lamps 414 may be arranged. In addition, process module 102 may include a second upper heater array 410 positioned above the second upper wall 432 of the second process chamber 310 and may comprise a second lamp housing 412 in which a second plurality of lamps 416 may be arranged. In some embodiments, each one of the first plurality of lamps 414 and each one of the second plurality of lamps 416 may be positioned to extend laterally across and above the first upper wall 430 of the first process chamber 308 and second process chamber 310, respectively. In some embodiments, the first plurality of lamps 414 and the second plurality of lamps 416 may be longitudinally spaced above the first upper wall 430 of the first process chamber 308 and the second process chamber 310 to enable uniform heating of the first substrate 118 and the second substrate 122 disposed within the first process volume 402 and second process volume 404, respectively. As used herein, the longitudinal axis (e.g., z axis) of the process chambers (either 308 or 310) can refer to extensions/directions parallel, or substantially parallel, to the central plane 314, whereas the planar axes (e.g., x and y axes) of the process chambers can refer to extensions/directions perpendicular, or substantially perpendicular, to the central plane 314.

In another aspect, the process module 102 may comprise a first lower heater array 418 positioned below the first lower wall 434 of the first process chamber 308 and comprising a third lamp housing 420 in which a plurality of third lamps 426 are arranged. In another aspect, process module 102 may comprise a second lower heater array 422 positioned below the second lower wall 436 of the second process chamber 310 and comprising a fourth lamp housing 424 in which a plurality of fourth lamps 428 are arranged.

In some embodiments, each one of the plurality of third lamps 426 and each one of the plurality of fourth lamps 428 may be positioned to extend longitudinally across and below the first and second upper walls of the first process chamber 308 and second process chamber 310, respectively. In some embodiments, the plurality of third lamps 426 and the plurality of fourth lamps 428 are longitudinally spaced below the first and second lower walls of the first process chamber 308 and the second process chamber 310.

The various heater arrays described above (i.e., 406, 410, 418, and 422 of FIG. 3) can be independently controlled (e.g., via a controller, such as the controller 108 of FIG. 2, for example) to enable, at least in part, autonomous temperature control of the first process volume 402 and the second process volume 404. In another aspect, independent temperature control between the first process volume 402 and the second process volume 404 can be realized, at least in part, by utilizing a cooling system to provide a coolant fluid flow between the first process chamber 308 and the second process chamber 310 thereby at least partially providing temperature isolation between the first process chamber 308 and the second process chamber 310 and their associated interior process volumes.

The first process chamber 308 and the second process chamber 310 can be laterally separated by a longitudinal coolant channel 322. In some embodiments, the longitudinal coolant channel 322 is defined, at least in part, by a channel formed by the separation between a portion of the first chamber exterior 324 proximate to the central plane 314 and a portion of the second chamber exterior 332 proximate to the central plane 314. In some embodiments, the longitudinal coolant channel 322 is defined, at least in part, by a channel formed by the separation between external surfaces of the first and second process chambers that are proximate to the central plane 314.

In some embodiments, the longitudinal coolant channel 322 can be defined (or further defined) by one or more septum members, which are configured to allow the coolant fluid flow across the one or more septum members to control the temperature of the first process volume 402 further independently and the second process volume 404. In exemplary embodiments, the process module 102 can further comprise a first longitudinal septum member 326 and a second longitudinal septum member 328. In such examples, the first longitudinal septum member 326 and the second longitudinal septum member 328 can extend longitudinally between the first and second injection chamber flanges (336, 338) and the first and second exhaust flanges (340, 342) of the first and second process chambers (308, 310).

In various embodiments, the longitudinal coolant channel and/or the longitudinal septum members can be coupled to a cooling system configured to provide a flow of coolant fluid into and through the longitudinal coolant channel. As a non-limiting example, the process module 102 can include the cooling system 344, which is configured to provide a flow of coolant fluid through the longitudinal coolant channel 322 and/or the first longitudinal septum member 326 and the second longitudinal septum member 328. In various embodiments, the cooling system 344 may comprise a blower arrangement (or multi-blower arrangements) configured to provide a flow of temperature-controlled (e.g., cooled) air longitudinally through the longitudinal coolant channel 322. In various embodiments, the first process chamber and the second process chamber of the dual chamber process modules of the present disclosure comprise ceramic weldments, including monolithic quartz assemblies configured to be housed in a common housing, and each process chamber is further configured to couple to an injection flange and an exhaust flange. In various embodiments, the process module 102 comprises a first process chamber 308 comprising a first upper wall 430 and a first lower wall 434. The first upper wall 430 extends longitudinally between a first injection chamber flange 336 and a longitudinally opposite first exhaust chamber flange 340. The first lower wall 434 is below and parallel relative to the first upper wall 430.

The process module 102 may include the first susceptor 120 for supporting the first substrate 118 and a second susceptor 124 for supporting the second substrate 122. For loading/unloading of the first substrate 118, the first susceptor 120 may be configured to be vertically movable (e.g., along the z axis) by being connected to a lift and rotate unit 450. For loading/unloading of the second substrate 122, the second susceptor 124 may also be configured to be vertically movable (e.g., along the z axis) by being connected to the lift and rotate unit 450. The lift and rotate unit 450 may be further configured to rotate the first susceptor 120 and/or the second susceptor 124 about a rotation axis (e.g., the z axis) during the deposition of the material layer onto the first substrate 118 and/or the second substrate 122.

A first plate 458 and a second plate 468 may be arranged between the first susceptor 120 and the lift and rotate unit 450. The second plate 468 may be connected to the lift and rotate unit 450. The first plate 458 and the second plate 468 may be connected to each other through a support unit 460. The first plate 458, the second plate 468, and the first susceptor 120 may move by the driving of the lift and rotate unit 450. In more detail, a driving force generated by the lift and rotate unit 450 may be transmitted to the second plate 468, and the transmitted driving force may be transmitted from the second plate 468 to the first plate 458 through the support unit 460. As a result, the first susceptor 120 connected to the first plate 458 may also be moved by the driving of the lift and rotate unit 450.

A first plate 462 and a second plate 466 may be arranged between the second susceptor 124 and the lift and rotate unit 450. The second plate 466 may be connected to the lift and rotate unit 450. The first plate 462 and the second plate 466 may be connected to each other through a support unit 464. The first plate 462, the second plate 466, and the second susceptor 124 may move by the driving of the lift and rotate unit 450. In more detail, a driving force generated by the lift and rotate unit 450 may be transmitted to the second plate 466, and the transmitted driving force may be transmitted from the second plate 466 to the first plate 462 through the support unit 464. As a result, the second susceptor 124 connected to the first plate 462 may also be moved by the driving of the lift and rotate unit 450.

In some examples, the lift and rotate unit 450 may simultaneously move and/or rotate the first susceptor 120 and the second susceptor 124. In some examples, the lift and rotate unit 450 may simultaneously move and/or rotate the first susceptor 120 while not moving and/or rotating the second susceptor 124. In some examples, the lift and rotate unit 450 may simultaneously move and/or rotate the second susceptor 124 while not moving and/or rotating the first susceptor 120.

The first plate 458 and/or the first plate 462 may be further coupled to a substrate alignment assembly 452. The substrate alignment assembly 452 may be configured to tilt or change the planar orientation of the first substrate 118 by moving the first plate 458. By moving the first plate 458, the substrate alignment assembly 452 may change the planar orientation of the first susceptor 120 supporting the first substrate 118. Changing the planar orientation of the first susceptor 120 would, in turn, change the planar orientation of the first substrate 118. Similarly, the substrate alignment assembly 452 may be configured to tilt or change the planar orientation of the second substrate 122 by moving the first plate 462. By moving the first plate 462, the substrate alignment assembly 452 may change the planar orientation of the second susceptor 124 supporting the second substrate 122. Changing the planar orientation of the second susceptor 124 would, in turn, change the planar orientation of the second substrate 122. The second plates 466 and 468 may not move, while the first plates 458 and 462 are being controlled by the substrate alignment assembly 452.

The lift and rotate unit 450 and the substrate alignment assembly 452 may have movement ranges of different scales. The lift and rotate unit 450 may have a movement range of, for example, several tens of centimeters, while the substrate alignment assembly 452 may have a movement range of several millimeters.

The support units 460 and 464 may be configured to support the first plates 458 and 462, respectively. In more detail, a static support function and a dynamic support function for the support units 460 and 464 may be performed. First, with respect to the static support function, the support units 460 and 464 may be configured to provide a fixing force for fixing the first plates 458 and 462, respectively, so that the first susceptor 120 and the second susceptor 124 may be maintained at a certain intended position. With respect to the dynamic support function, when the first plates 458 and 462 are moved by the substrate alignment assembly 452, the support units 460 and 464 may allow the first plates 458 and 462 to move. The support units 460 and 464 may provide a support force for the first plates 458 and 462 while allowing the movement of the first plates 458 and 462. In other words, the support units 460 and 464 may support the first plates 458 and 462 with respect to the relative movement of the first plates 458 and 462 with respect to the second plates 466 and 468, and the support units 460 and 464 may support the first plates 458 and 462 in a dynamic state of the first plates 458 and 462. The support units 460 and 464 may be configured to transmit a fixing force of the second plates 466 and 468 with respect to the first plates 458 and 462 connected to the first susceptor 120 and the second susceptor 124, respectively. In other words, the support units 460 and 464 may connect the second plates 466 and 468 to the first plates 458 and 462, respectively, such that a driving force generated by the lift and rotate unit 450 may be transmitted from the second plates 466 and 468 to the first plates 458 and 462. A bolt or the like may be used for such a connection mechanism. According to embodiments, the support units 460 and 464 may prevent the first plates 458 and 462 from being over-constrained by the substrate alignment assembly 452.

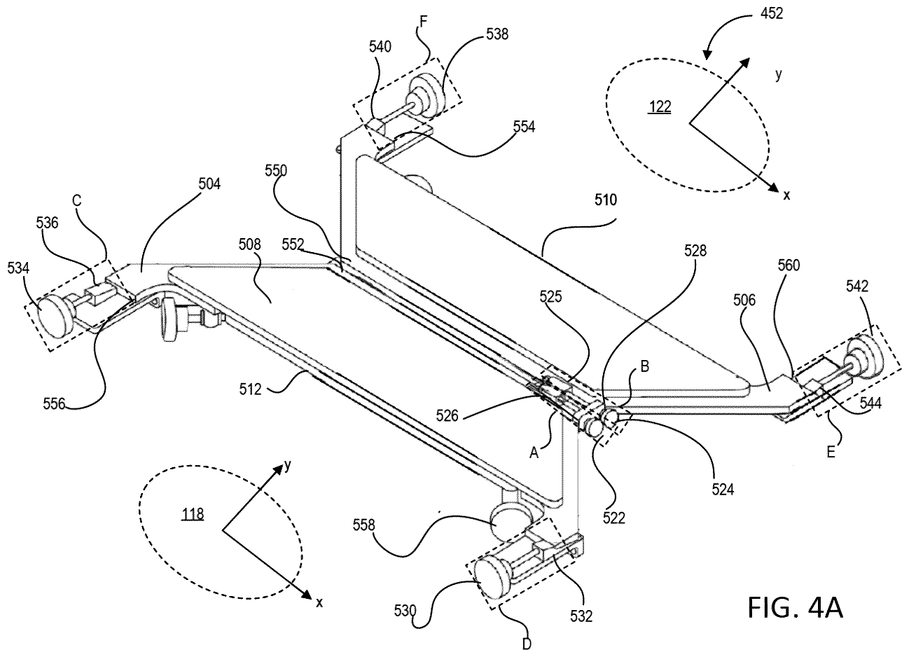

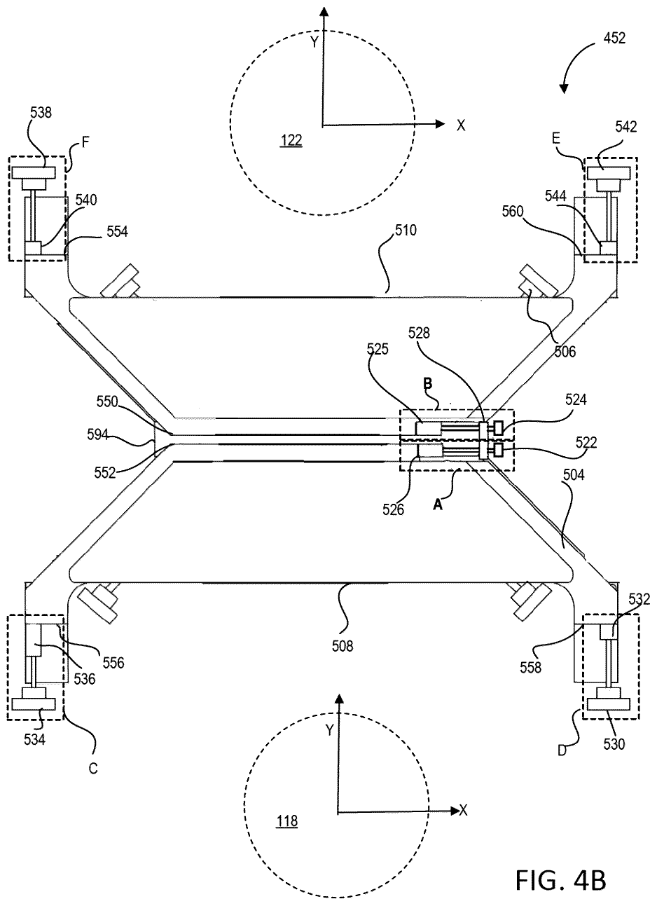

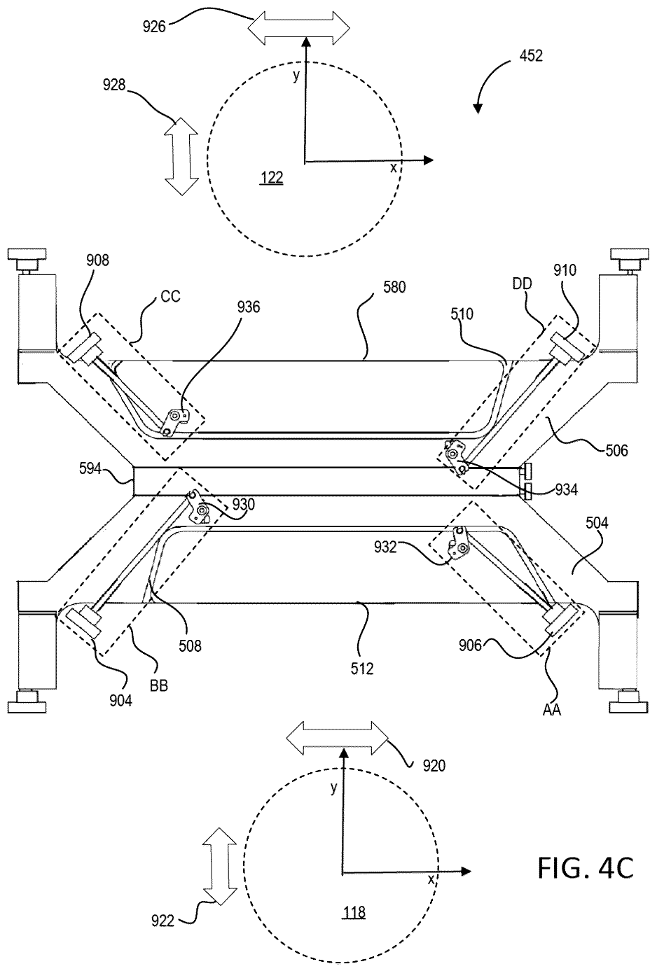

For purposes of explanation and illustration, and not limitation, an exemplary substrate alignment assembly 452 is illustrated in FIGS. 4A, 4B, and 4C. FIG. 4A illustrates a side view of the substrate alignment assembly 452, while FIG. 4B illustrates the top view of the substrate alignment assembly 452 and FIG. 4C illustrates the bottom view of the substrate alignment assembly 452.

As shown in FIG. 4A, the substrate alignment assembly 452 may be disposed on top of or be supported by a frame (not shown in drawings). The frame 502 may be mounted to a wall of a dual chamber process module (e.g., the process module 102). The frame 502 may comprise a cross-like base structure with a middle bar. The frame may further comprise four vertical legs, one at each end of the X-shaped structure. Two of the four vertical legs may enable the frame to be mounted to the wall of a dual chamber process module.

The substrate alignment assembly 452 may comprise a first alignment plate 504, a first shifting plate 508, and/or a second shifting plate 512 (as shown in FIGS. 4A and 4C) for adjusting the planar orientation of the first substrate 118 (the outline of the first substrate 118 is shown in FIGS. 4A, 4B, and 4C) being supported by the first susceptor 120 in the first process chamber 308 of the dual chamber process module 102 (not shown in FIGS. 4A, 4B, and 4C). The first alignment plate 504 may be directly connected to the first shifting plate 508. The first shifting plate 508, in turn, may be connected to the second shifting plate 512. The first alignment plate 504 is not directly connected to the second shifting plate 512 and may only be coupled to the second shifting plate 512 via the first shifting plate 508. As shown in FIGS. 4A, 4B, and 4C, the first alignment plate 504 may be shaped as a trapezoid with a trapezoidal hole. The first shifting plate 508 may cover the trapezoidal hole of the first alignment plate 504 from the top (as shown in FIG. 4B). The second shifting plate 512 may be smaller than the hole of the trapezoidal hole of the first alignment plate 504, and may be attached to the bottom surface of the first shifting plate 508 (as shown in FIG. 4C). Various mechanisms may be used to couple plates in the substrate alignment assembly 452, such as bolts, nuts, screws, and the like.

The first alignment plate 504, the first shifting plate 508, and a second shifting plate 512 may be coupled in such a fashion that when the first alignment plate 504 is independently moved, the first shifting plate 508 and the second shifting plate 512 moves with the first alignment plate 504. However, when the first shifting plate 508 is independently moved, the second shifting plate 512 may move with the first shifting plate 508, but the first alignment plate 504 will not move with the first shifting plate 508. When the second shifting plate 512 is independently moved, the first alignment plate 504 and the first shifting plate 508 do not move with the second shifting plate 512.

The second shifting plate 512 may be coupled to a first plate of a susceptor in one of the process chambers of the dual chamber process module (e.g., the process module). For example, the second shifting plate 512 may be coupled to the first plate 458 which is connected to the first susceptor 120 supporting the first substrate 118 in the first process chamber 308.

The first alignment plate 504 may be configured to adjust or change the planar orientation of the first substrate 118 or tilt the first substrate 118 around the planar axes (e.g., the x axis and the y axis). For example, when the first alignment plate 504 is tilted, there may be a corresponding tilt in the first shifting plate 508 and the second shifting plate 512. The tilt in the second shifting plate 512 may cause the first plate 458 to tilt in the same fashion, which in turn may cause the first susceptor 120 to tilt. The tilting of the first susceptor 120 may cause the first substrate 118 to tilt as the first substrate is sitting on top of the first susceptor 120.

Furthermore, the substrate alignment assembly 452 may comprise a second alignment plate 506, a third shifting plate 510, and/or a fourth shifting plate 580 (as shown in FIG. 4C) for adjusting the planar orientation of the second substrate 122 (the outline of the second substrate 122 is shown in FIGS. 4A, 4B, and 4C) being supported by the second susceptor 124 in the second process chamber 310 of the dual chamber process module 102 (not shown in FIGS. 4A, 4B, and 4C). The second alignment plate 506 may be directly connected to the third shifting plate 510. The third shifting plate 510, in turn, may be connected to the fourth shifting plate 580. The second alignment plate 506 is not directly connected to the fourth shifting plate 580 and may only be coupled to the fourth shifting plate 580 via the third shifting plate 510. As shown in FIGS. 4A, 4B, and 4C, similar to the first alignment plate 504, the second alignment plate 506 may be shaped as a trapezoid with a trapezoidal hole. The third shifting plate 510 may cover the trapezoidal hole of the second alignment plate 506 from the top (as shown in FIG. 4B). The fourth shifting plate 580 may be smaller than the hole of the trapezoidal hole of the second alignment plate 506, and may be attached to the bottom surface of the third shifting plate 510 (as shown in FIG. 4C).

The second alignment plate 506, the third shifting plate 510, and a fourth shifting plate 580 may be coupled in such a fashion that when the second alignment plate 506 is independently moved, the third shifting plate 510 and the fourth shifting plate 580 may move with the second alignment plate 506. However, when the third shifting plate 510 is independently moved, the fourth shifting plate 580 may move with the third shifting plate 510, but the second alignment plate 506 will not move with the third shifting plate 510. When the fourth shifting plate 580 is independently moved, the second alignment plate 506 and the third shifting plate 510 do not move with the fourth shifting plate 580.

The fourth shifting plate 580 may be coupled to a first plate 462 which is connected to the second susceptor 124 supporting the second substrate 122 in the second process chamber 310. The second alignment plate 506 may be configured to adjust or change the planar orientation of the second substrate 122 or tilt the second substrate 122 around the planar axes (e.g., the x axis and the y axis). For example, when the second alignment plate 506 is tilted, there may be a corresponding tilt in the third shifting plate 510 and the second shifting plate 512. The tilt in the fourth shifting plate 580 may cause the first plate 462 to tilt in the same fashion, which in turn may cause the second susceptor 124 to tilt. The tilting of the second susceptor 124 may cause the second substrate 122 to tilt as the second substrate 122 is sitting on top of the second susceptor 124.

As shown in FIGS. 4A and 4B, the first alignment plate 504 may comprise a first side 552 facing a first side 550 of the second alignment plate 506. The first side 552 of the first alignment plate 504 may be spaced 5 to 20 millimeters from the first side 550 of the second alignment plate 506.

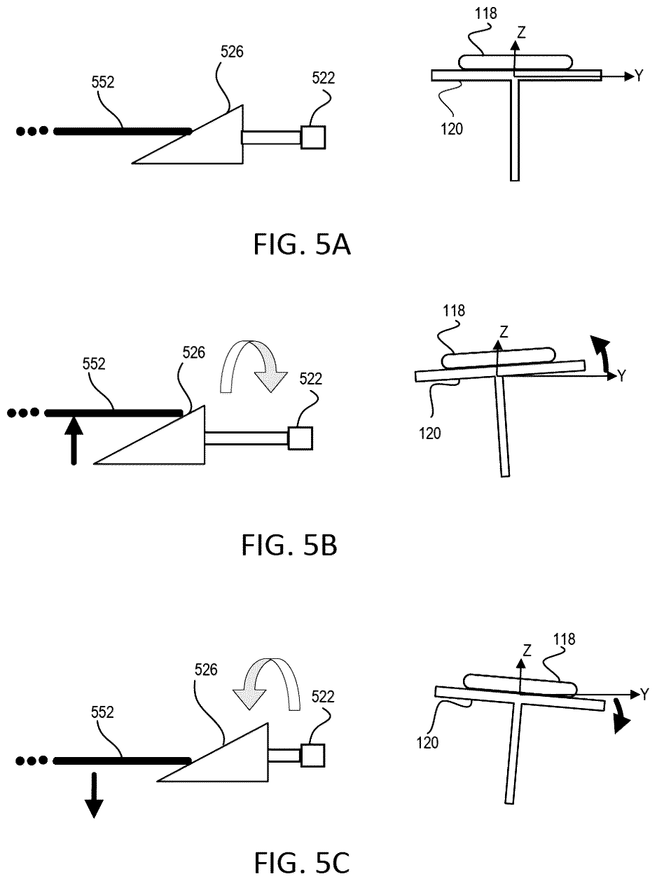

The substrate alignment assembly 452 may comprise a first tilting unit A comprising an adjustment mechanism 522 and a wedge 526. The first tilting unit A may be configured to tilt the first alignment plate 504 around the x axis or the y-z plane, which may cause a corresponding tilt in the first susceptor 120 and the first substrate 118. The adjustment mechanism 522 may be attached to the wedge 526. As shown in FIG. 5A, a lower portion of the wedge 526 may be under the first side 552 of the first alignment plate 504 even when the first substrate 118 and the first susceptor 120 are parallel to the upper and lower walls of the first process chamber 308 (not shown in FIG. 5A). As shown in FIG. 5B, when the adjustment mechanism 522 is turned in a first direction (e.g., clockwise, or anti-clockwise), the wedge 526 may be pushed further under the first side 552 of the first alignment plate 504. Driving the wedge 526 further under the first side 552 of the first alignment plate 504 may cause the first alignment plate 504 to tilt or rotate upward around the x axis or the y-z plane, which may further cause a corresponding upward tilt or rotation around the x axis or the y-z plane in the first susceptor 120 and the first substrate 118. Additionally, or alternatively, as shown in FIG. 5C, when the adjustment mechanism 522 is turned in a second direction that is opposite the first direction, the wedge 526 may be removed from under the first side 552 of the first alignment plate 504. Removing the wedge 526 from under the first side 552 of the first alignment plate 504 may cause the first alignment plate 504 to tilt or rotate downward around the x axis or the y-z plane, which may further cause a corresponding downward tilt or rotation around the x axis or the y-z plane in the first susceptor 120 and the first substrate 118.

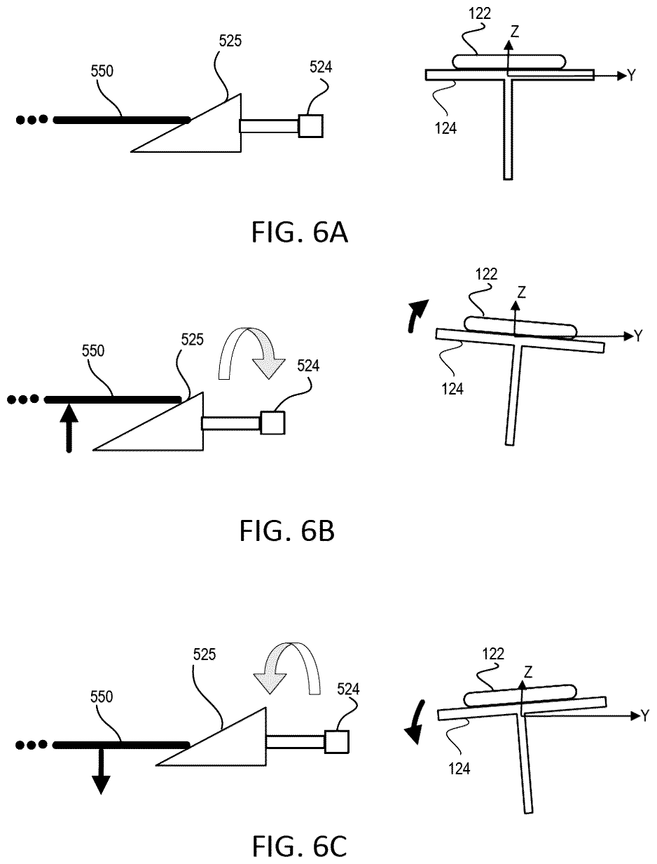

Additionally, the substrate alignment assembly 452 may comprise a second tilting unit B comprising an adjustment mechanism 524 and a wedge 525. The second tilting unit B may be configured to tilt the second alignment plate 506 around the x axis or the y-z plane, which may cause a corresponding tilt in the second susceptor 124 and the second substrate 122. The adjustment mechanism 524 may be attached to the wedge 525. As shown in FIG. 6A, a lower portion of the wedge 525 may be under the first side 550 of the second alignment plate 506 even when the second substrate 122 and the second susceptor 124 are parallel to the upper and lower walls of the second process chamber 310 (not shown in FIG. 6A). As shown in FIG. 6B, when the adjustment mechanism 524 is turned in a first direction (e.g., clockwise, or anti-clockwise), the wedge 525 may be pushed further under the first side 550 of the second alignment plate 506. Driving the wedge 525 further under the first side 550 of the second alignment plate 506 may cause the second alignment plate 506 to tilt or rotate upward around the x axis or the y-z plane, which may further cause a corresponding upward tilt or rotation around the x axis or the y-z plane in the second susceptor 124 and the second substrate 122. Additionally, or alternatively, as shown in FIG. 6C, when the adjustment mechanism 524 is turned in a second direction that is opposite the first direction, the wedge 525 may be removed from under the first side 550 of the second alignment plate 506. Removing the wedge 525 from under the first side 550 of the second alignment plate 506 may cause the first alignment plate 504 to tilt or rotate downward around the x axis or the y-z plane, which may further cause a corresponding downward tilt or rotation around the x axis or the y-z plane in the second susceptor 124 and the second substrate 122.

Referring back to FIGS. 4A and 4B, in some examples, the adjustment mechanism 522 and the adjustment mechanism 524 may be attached to the middle bar 594 (shown in FIG. 4B) of the frame supporting the substrate alignment assembly 452 by a fastener 528 (e.g., a clamp). In some examples, the stem of the adjustment mechanism 522 may be parallel to the stem of the adjustment mechanism 524.

Additionally, the substrate alignment assembly 452 may further comprise a third tilting unit C at corner 556 of the second alignment plate 506 and/or a fourth tilting unit D at corner 558 of the second alignment plate 506. The corners 556 and 558 may be on the second side of the second alignment plate 506, and the second side may be opposite the first side 552 of the second alignment plate 506. The third tilting unit C at the corner 556 may comprise an adjustment mechanism 534 and a wedge 536, where the adjustment mechanism 534 may be attached to the wedge 536. The fourth tilting unit D at the corner 558 may comprise an adjustment mechanism 530 and a wedge 532, where the adjustment mechanism 530 may be attached to the wedge 532. The third tilting unit C and/or the fourth tilting unit D may be configured to tilt the first alignment plate 504 around the y axis or the x-z plane, which may cause a corresponding tilt in the first susceptor 120 and the first substrate 118. A stem of the adjustment mechanism 530 and a stem of the adjustment mechanism 534 may be parallel to each other. In some examples, the adjustment mechanisms 530 and 532 may be knurled knobs, jack screws, thumb screws with knurled heads, threaded adjustment knobs, handwheels, crank handles, rotary cam controls, tension control knobs, torque-setting dials, and the like.

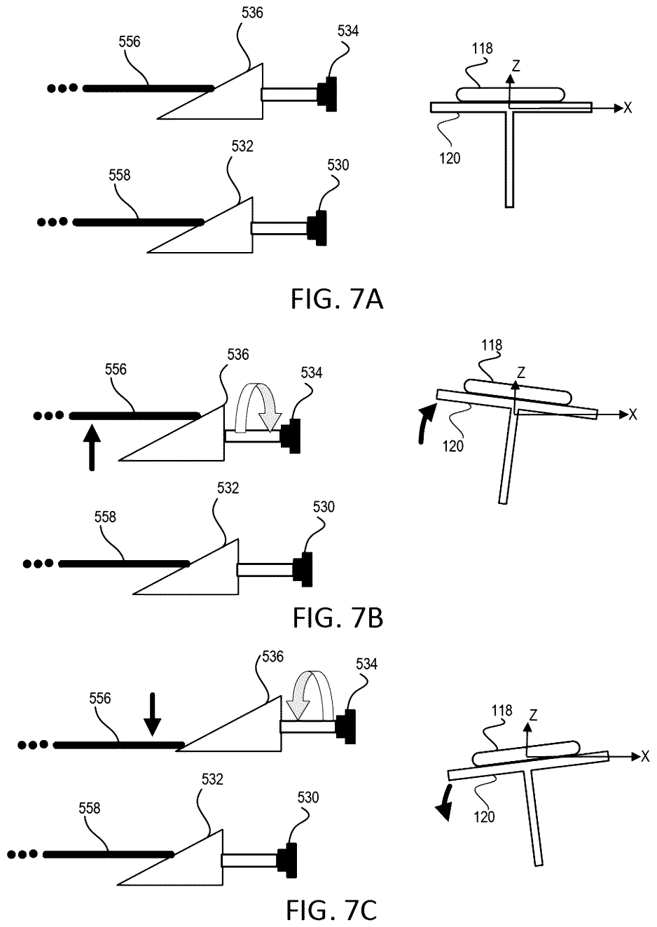

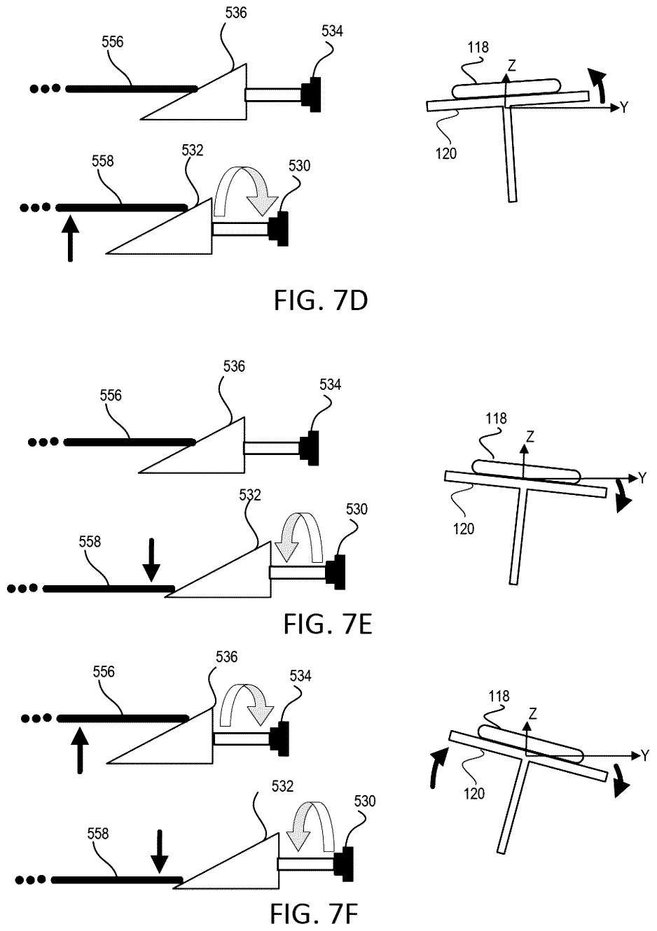

As shown in FIG. 7A, a lower portion of the wedge 536 may be under the corner 556 of the first alignment plate 504, and a lower portion of the wedge 532 may be under the corner 558 of the first alignment plate 504, even when the first substrate 118 and the first susceptor 120 are parallel to the upper and lower walls of the first process chamber 308 (not shown in FIG. 7A). As shown in FIG. 7B, when the adjustment mechanism 534 is turned in a first direction (e.g., clockwise, or anti-clockwise) without turning the adjustment mechanism 530, the wedge 536 may be pushed further under the corner 556 of the first alignment plate 504. Driving the wedge 536 further under the corner 556 of the first alignment plate 504 may cause the first alignment plate 504 to tilt or rotate upward around the y axis or the x-z plane, which may further cause a corresponding upward tilt or rotation around the y axis or the x-z plane in the first susceptor 120 and the first substrate 118. Additionally, or alternatively, as shown in FIG. 7C, when the adjustment mechanism 534 is turned in a second direction that is opposite the first direction without turning the adjustment mechanism 530, the wedge 536 may be removed from under the corner 556 of the first alignment plate 504. Removing the wedge 536 from under the corner 556 of the first alignment plate 504 may cause the first alignment plate 504 to tilt or rotate downward around the y axis or the x-z plane, which may further cause a corresponding downward tilt or rotation around the y axis or the x-z plane in the first susceptor 120 and the first substrate 118. As shown in FIG. 7D, when the adjustment mechanism 530 is turned in a first direction (e.g., clockwise, or anti-clockwise) without turning the adjustment mechanism 534, the wedge 532 may be pushed further under the corner 558 of the first alignment plate 504. Driving the wedge 532 further under the corner 558 of the first alignment plate 504 may cause the first alignment plate 504 to tilt or rotate upward around the y axis or the x-z plane, which may further cause a corresponding upward tilt or rotation around the y axis or the x-z plane in the first susceptor 120 and the first substrate 118. Additionally, or alternatively, as shown in FIG. 7E, when the adjustment mechanism 530 is turned in a second direction that is opposite the first direction without turning the adjustment mechanism 534, the wedge 532 may be removed from under the corner 558 of the first alignment plate 504. Removing the wedge 532 from under the corner 558 of the first alignment plate 504 may cause the first alignment plate 504 to tilt or rotate downward around the y axis or the x-z plane, which may further cause a corresponding downward tilt or rotation around the y axis or the x-z plane in the first susceptor 120 and the first substrate 118. In some examples, both the adjustment mechanism 530 and the adjustment mechanism 534 may be turned (e.g., turned in the opposite direction) to tilt or rotate the first substrate 118 around the y axis or the x-z plane. For example, as shown in FIG. 7F, the adjustment mechanism 534 may be turned in a first direction (e.g., clockwise, or anti-clockwise) such that the wedge 536 may be pushed further under the corner 556 of the first alignment plate 504. Furthermore, the adjustment mechanism 530 may be turned in a second direction that is opposite the first direction such that the wedge 532 may be removed from under the corner 558 of the first alignment plate 504. Turning both the adjustment mechanism 530 and the adjustment mechanism 534 may cause the first alignment plate 504 to tilt or rotate downward around the y axis or the x-z plane, which may further cause a corresponding downward tilt or rotation around the y axis or the x-z plane in the first susceptor 120 and the first substrate 118.

An adjustment in the planar orientation of the first substrate 118 may comprise turning one or more of the adjustment mechanism 522, the adjustment mechanism 530, and the adjustment mechanism 534. An adjustment of the first substrate 118 may comprise both a rotation around the x axis (e.g., the y-z plane) by turning the adjustment mechanism 530 and/or the adjustment mechanism 534 and a rotation around the y axis (e.g., the x-z plane) by turning the adjustment mechanism 522.

Referring back to FIGS. 4A and 4B, the substrate alignment assembly 452 may further comprise a fifth tilting unit E at corner 560 of the second alignment plate 506 and/or a sixth tilting unit F at corner 554 of the second alignment plate 506. The corners 554 and 560 may be on the second side of the second alignment plate 506, and the second side may be opposite the first side 550 of the second alignment plate 506. The fifth tilting unit E at the corner 560 may comprise an adjustment mechanism 542 and a wedge 544 (as shown in FIG. 4B), where the adjustment mechanism 542 may be attached to the wedge 544. The sixth tilting unit F at the corner 554 may comprise an adjustment mechanism 538 and a wedge 540, where the adjustment mechanism 538 may be attached to the wedge 540. Similar to the third tilting unit C and the fourth tilting unit D, the fifth tilting unit E and/or the sixth tilting unit F may be configured to tilt the second alignment plate 506 around the y axis or the x-z plane, which may cause a corresponding tilt in the second susceptor 124 and the second substrate 122. A stem of the adjustment mechanism 538 and a stem of the adjustment mechanism 542 may be parallel to each other. An adjustment in the planar orientation of the second substrate 122 may comprise turning one or more of the adjustment mechanism 524, the adjustment mechanism 542, and the adjustment mechanism 538. In some examples, an adjustment of the second substrate 122 may comprise only a rotation around the y axis (e.g., the x-z plane) by turning the adjustment mechanism 524. In some examples, an adjustment of the second substrate 122 may comprise only a rotation around the x axis (e.g., the y-z plane) by turning the adjustment mechanism 538 and/or the adjustment mechanism 542. In some examples, an adjustment of the second substrate 122 may comprise both a rotation around the y axis (e.g., the x-z plane) by turning the adjustment mechanism 524 and a rotation around the x axis (e.g., the y-z plane) by turning the adjustment mechanism 538 and/or the adjustment mechanism 542. In some examples, the adjustment mechanisms 538 and 542 may be knurled knobs, jack screws, thumb screws with knurled heads, threaded adjustment knobs, handwheels, crank handles, rotary cam controls, tension control knobs, torque-setting dials, and the like.

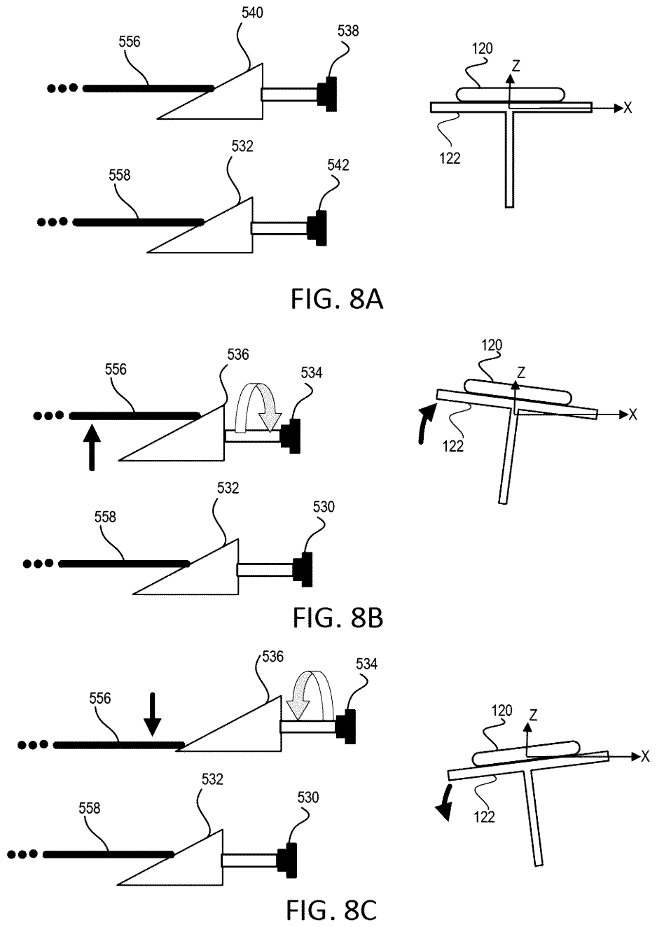

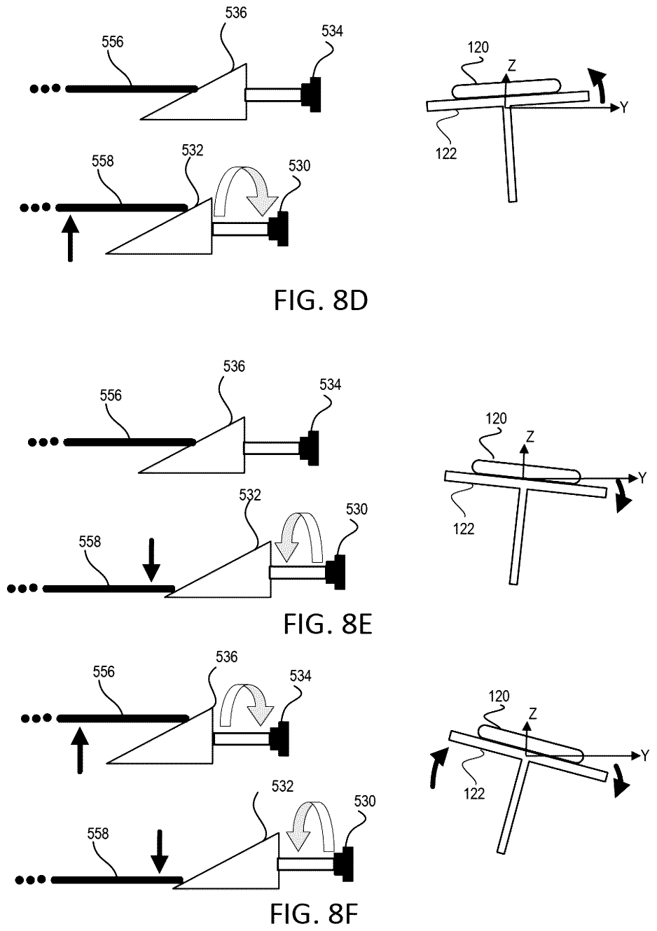

For example, as shown in FIG. 8A, a lower portion of the wedge 540 may be under the corner 554 of the second alignment plate 506, and a lower portion of the wedge 544 may be under the corner 560 of the second alignment plate 506, even when the second substrate 122 and the second susceptor 124 are parallel to the upper and lower walls of the second process chamber 310 (not shown in FIG. 8A). As shown in FIG. 8B, when the adjustment mechanism 538 is turned in a first direction (e.g., clockwise, or anti-clockwise) without turning the adjustment mechanism 542, the wedge 540 may be pushed further under the corner 554 of the second alignment plate 506. Driving the wedge 540 further under the corner 554 of the second alignment plate 506 may cause the second alignment plate 506 to tilt or rotate upward around the y axis or the x-z plane, which may further cause a corresponding upward tilt or rotation around the y axis or the x-z plane in the second susceptor 124 and the second substrate 122. Additionally, or alternatively, as shown in FIG. 8C, when the adjustment mechanism 540 is turned in a second direction that is opposite the first direction without turning the adjustment mechanism 542, the wedge 540 may be removed from under the corner 554 of the second alignment plate 506. Removing the wedge 540 from under the corner 554 of the second alignment plate 506 may cause the second alignment plate 506 to tilt or rotate downward around the y axis or the x-z plane, which may further cause a corresponding downward tilt or rotation around the y axis or the x-z plane in the second susceptor 124 and the second substrate 122.

As shown in FIG. 8D, when the adjustment mechanism 542 is turned in a first direction (e.g., clockwise, or anti-clockwise) without turning the adjustment mechanism 538, the wedge 544 may be pushed further under the corner 560 of the second alignment plate 506. Driving the wedge 544 further under the corner 560 of the second alignment plate 506 may cause the second alignment plate 506 to tilt or rotate upward around the y axis or the x-z plane, which may further cause a corresponding upward tilt or rotation around the y axis or the x-z plane in the second susceptor 124 and the second substrate 122. Additionally, or alternatively, as shown in FIG. 7E, when the adjustment mechanism 542 is turned in a second direction that is opposite the first direction without turning the adjustment mechanism 538, the wedge 544 may be removed from under the corner 560 of the second alignment plate 506. Removing the wedge 544 from under the corner 560 of the second alignment plate 506 may cause the second alignment plate 506 to tilt or rotate downward around the y axis or the x-z plane, which may further cause a corresponding downward tilt or rotation around the y axis or the x-z plane in the second susceptor 124 and the second substrate 122. In some examples, both the adjustment mechanism 538 and the adjustment mechanism 542 may be turned (e.g., turned in opposite direction) to tilt or rotate the second substrate 122 around the y axis or the x-z plane. For example, as shown in FIG. 8F, the adjustment mechanism 538 may be turned in a first direction (e.g., clockwise, or anti-clockwise) such that the wedge 540 may be pushed further under the corner 554 of the second alignment plate 506. Furthermore, the adjustment mechanism 542 may be turned in a second direction that is opposite the first direction such that the wedge 544 may be removed from under the corner 560 of the second alignment plate 506. Turning both the adjustment mechanism 538 and the adjustment mechanism 542 may cause the second alignment plate 506 to tilt or rotate downward around the y axis or the x-z plane, which may further cause a corresponding downward tilt or rotation around the y axis or the x-z plane in the second susceptor 124 and the second substrate 122.

Referring back to FIG. 4C, a bottom side of the substrate alignment assembly 452 may comprise a first shifting unit AA comprising an adjustment mechanism 906 and a bracket 930 connected to the adjustment mechanism 906. The first shifting unit AA may be connected to the first shifting plate 508. Turning the adjustment mechanism 906 in a first direction (e.g., clockwise, or anti-clockwise) or a second direction opposite to the first direction may cause the first shifting plate 508 and the second shifting plate 512 to make a movement 920 along the x-x′ axis. The bottom side of the substrate alignment assembly 452 may further comprise a second shifting unit BB comprising an adjustment mechanism 904 and a bracket 932 connected to the adjustment mechanism 904. The second shifting unit BB may be connected to the second shifting plate 512. Turning the adjustment mechanism 904 in a first direction (e.g., clockwise, or anti-clockwise) or a second direction opposite to the first direction may cause the second shifting plate 512 to make a movement 922 along the y-y′ axis. The first shifting unit AA and the second shifting unit BB may be used to center the first substrate 118 in the first process chamber 308 by centering the first susceptor 120 by turning the adjustment mechanism 904 and/or the adjustment mechanism 906.

Additionally, the bottom side of the substrate alignment assembly 452 may comprise a third shifting unit CC comprising an adjustment mechanism 908 and a bracket 934 connected to the adjustment mechanism 908. The third shifting unit CC may be connected to the third shifting plate 510. Turning the adjustment mechanism 908 in a first direction (e.g., clockwise, or anti-clockwise) or a second direction opposite to the first direction may cause the third shifting plate 510 and the fourth shifting plate 580 to make a movement 926 along the x-x′ axis. The bottom side of the substrate alignment assembly 452 may further comprise a fourth shifting unit DD comprising an adjustment mechanism 910 and a bracket 936 connected to the adjustment mechanism 910. The fourth shifting unit DD may be connected to the fourth shifting plate 580. Turning the adjustment mechanism 910 in a first direction (e.g., clockwise, or anti-clockwise) or a second direction opposite to the first direction may cause the fourth shifting plate 580 to make a movement 928 along the y-y′ axis. The third shifting unit CC and the fourth shifting unit DD may be used to center the second substrate 122 in the second process chamber 310 by centering the second susceptor 124 by turning the adjustment mechanism 908 and/or the adjustment mechanism 910. In some examples, the adjustment mechanisms 904, 906, 908, and 910 may be knurled knobs, jack screws, thumb screws with knurled heads, threaded adjustment knobs, handwheels, crank handles, rotary cam controls, tension control knobs, torque-setting dials, and the like.

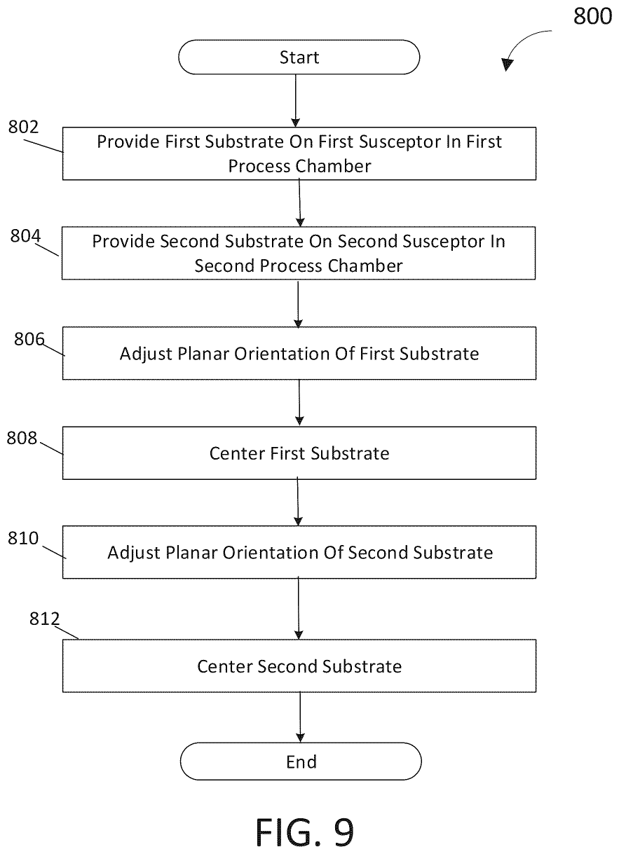

FIG. 9 illustrates an example method 800 of aligning substrates (e.g., the first substrate 118 and the second substrate 122) in a dual chamber process module (e.g., the dual chamber process module 102) in accordance with one or more embodiments of the disclosure. The steps in the method 800 may be performed by a controller (e.g., the controller 108) coupled to the semiconductor processing system or a human operator. In some examples, the adjustment mechanism 522, the adjustment mechanism 524, the adjustment mechanism 530, the adjustment mechanism 534, the adjustment mechanism 538, the adjustment mechanism 542, the adjustment mechanism 904, the adjustment mechanism 906, the adjustment mechanism 908, and/or the adjustment mechanism 910 may be coupled to the controller 108, and the turnings can be controlled by the controller 108. The example steps in FIG. 9 may be performed in different orders and with different, fewer, or additional steps than those illustrated. Some steps may be omitted, while multiple steps may be combined. In some examples, the adjustment mechanisms 522 and 524 may be knurled knobs, jack screws, thumb screws with knurled heads, threaded adjustment knobs, handwheels, crank handles, rotary cam controls, tension control knobs, torque-setting dials, and the like.

As shown in FIG. 9, step 802 of method 800 may include providing the first substrate 118 in the first process chamber 308. The first substrate 118 may be supported by the first susceptor 120 inside the first process chamber 308. At step 804, a second substrate 122 may be provided inside the second process chamber 310. The second substrate 122 may be supported by the second susceptor 124 inside the second process chamber 310. The first susceptor 120 and/or the second susceptor 124 may be coupled to the substrate alignment assembly 452, as described in detail above.

At step 806, the planar orientation of the first substrate 118 may be adjusted by turning one or more of the adjustment mechanism 522, the adjustment mechanism 530, and the adjustment mechanism 534 of the substrate alignment assembly 452 (as shown in FIGS. 4A, 4B, 6A-C, and 8A-F). At step 808, the first substrate 118 may be centered by turning one or more of the adjustment mechanism 904 and the adjustment mechanism 906 of the substrate alignment assembly 452 (as shown in FIG. 4C). At step 810, the planar orientation of the second substrate 122 may be adjusted by turning one or more of the adjustment mechanism 524, the adjustment mechanism 538, and the adjustment mechanism 542 of the substrate alignment assembly 452 (as shown in FIGS. 4A, 4B, 5A-C, 6A-C). At step 812, the second substrate 122 may be centered by turning one or more of the adjustment mechanism 908 and the adjustment mechanism 910 of the substrate alignment assembly 452 (as shown in FIG. 4C).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A semiconductor processing system comprising:
a first susceptor in a first process chamber of a dual chamber process module, wherein the first susceptor is configured to hold a first substrate;
a second susceptor in a second process chamber of the dual chamber process module, wherein the second susceptor is configured to hold a second substrate; and
a substrate alignment assembly configured to cause:
a first adjustment of a first planar orientation of the first susceptor; and
a second adjustment of a second planar orientation of the second susceptor, wherein the first adjustment is independent of the second adjustment.

2. The semiconductor processing system of claim 1, wherein the substrate alignment assembly comprises:
a first alignment plate coupled to the first susceptor; and
a second alignment plate coupled to the second susceptor,
wherein each of the first alignment plate and the second alignment plate comprises a first side and a second side parallel to the first side;
wherein a first tilting of the first alignment plate causes a first corresponding tilting in the first susceptor; and
wherein a second tilting of the second alignment plate causes a second corresponding tilting in the second susceptor.

3. The semiconductor processing system of claim 2, wherein the substrate alignment assembly further comprises:
a first tilting unit configured to tilt the first susceptor around a first planar axis by tilting the first side of the first alignment plate; and
a second tilting unit configured to tilt the second susceptor around the first planar axis by tilting the first side of the second alignment plate.

4. The semiconductor processing system of claim 3, wherein each of the first tilting unit and the second tilting unit comprises a wedge and an adjustment mechanism coupled to the wedge;
wherein turning, in a first direction, the adjustment mechanism of the first tilting unit drives the wedge of the first tilting unit under the first side of the first alignment plate and tilts the first side of the first alignment plate upward;
wherein turning, in a second direction, the adjustment mechanism of the first tilting unit removes the wedge of the first tilting unit from under the first side of the first alignment plate and tilts the first side of the first alignment plate downward;
wherein turning, in the first direction, the adjustment mechanism of the second tilting unit drives the wedge of the second tilting unit under the first side of the second alignment plate and tilts the first side of the second alignment plate upward; and
wherein turning, in the second direction, the adjustment mechanism of the second tilting unit removes the wedge of the second tilting unit from under the first side of the second alignment plate and tilts the first side of the second alignment plate downward.

5. The semiconductor processing system of claim 4, wherein the substrate alignment assembly further comprises a fastener coupling the adjustment mechanism of the first tilting unit and the adjustment mechanism of the second tilting unit.

6. The semiconductor processing system of claim 4, wherein a stem of the adjustment mechanism of the first tilting unit is parallel to a stem of the adjustment mechanism of the second tilting unit.

7. The semiconductor processing system of claim 2, wherein each of the first alignment plate and the second alignment plate comprises a trapezoid shape.

8. The semiconductor processing system of claim 2, wherein the substrate alignment assembly further comprises:
a third tilting unit configured to tilt the first susceptor around a second axis by tilting a first corner of the second side of the first alignment plate; and
a fourth tilting unit configured to tilt the second susceptor around the second axis by tilting a first corner of the second side of the second alignment plate.

9. The semiconductor processing system of claim 8, wherein each of the third tilting unit and the fourth tilting unit comprises a wedge and an adjustment mechanism coupled to the wedge;
wherein turning, in a first direction, the adjustment mechanism of the third tilting unit drives the wedge of the third tilting unit under the first corner of the second side of the first alignment plate and tilts the first corner of the second side of the first alignment plate upward;
wherein turning, in a second direction, the adjustment mechanism of the third tilting unit removes the wedge of the third tilting unit from under the first corner of the second side of the first alignment plate and tilts the first corner of the second side of the first alignment plate downward;
wherein turning, in the first direction, the adjustment mechanism of the fourth tilting unit drives the wedge of the fourth tilting unit under the first corner of the second side of the second alignment plate and tilts the first corner of the second side of the second alignment plate upward; and
wherein turning, in the second direction, the adjustment mechanism of the forth tilting unit removes the wedge of the fourth tilting unit from under the first corner of the second side of the second alignment plate and tilts the first corner of the second side of the second alignment plate downward.

10. The semiconductor processing system of claim 9, wherein the substrate alignment assembly further comprises:
a fifth tilting unit configured to tilt the first susceptor around the second axis by tilting a second corner of the second side of the first alignment plate; and
a sixth tilting unit configured to tilt the second susceptor around the second axis by tilting a second corner of the second side of the second alignment plate.

11. The semiconductor processing system of claim 10, wherein each of the fifth tilting unit and the sixth tilting unit comprises a second wedge and a second adjustment mechanism coupled to the second wedge;
wherein turning, in the first direction, the second adjustment mechanism of the fifth tilting unit drives the second wedge of the fifth tilting unit under the second corner of the second side of the first alignment plate and tilts the second corner of the second side of the first alignment plate upward;
wherein turning, in the second direction, the second adjustment mechanism of the fifth tilting unit removes the second wedge of the fifth tilting unit from under the second corner of the second side of the first alignment plate and tilts the second corner of the second side of the first alignment plate downward;
wherein turning, in the first direction, the second adjustment mechanism of the sixth tilting unit drives the second wedge of the sixth tilting unit under the second corner of the second side of the second alignment plate and tilts the second corner of the second side of the second alignment plate upward; and
wherein turning, in the second direction, the second adjustment mechanism of the sixth tilting unit removes the wedge of the sixth tilting unit from under the second corner of the second side of the second alignment plate and tilts the second corner of the second side of the second alignment plate downward.

12. The semiconductor processing system of claim 11, wherein a stem of the adjustment mechanism of the third tilting unit is parallel to a stem of the second adjustment mechanism of the fifth tilting unit; and
wherein a stem of the adjustment mechanism of the fourth tilting unit is parallel to a stem of the second adjustment mechanism of the sixth tilting unit.

13. The semiconductor processing system of claim 2, wherein the substrate alignment assembly comprises:
a first shifting plate coupled to the first alignment plate; and
a second shifting plate coupled to the first shifting plate,
wherein a first shifting of the first shifting plate causes a first corresponding shifting in the first susceptor along a first axis; and
wherein a second shifting of the second shifting plate causes a second corresponding shifting in the first susceptor along a second axis.

14. The semiconductor processing system of claim 13, wherein the first shifting of the first shifting plate or the second shifting of the second shifting plate does not change the first planar orientation of the first susceptor.

15. The semiconductor processing system of claim 13, wherein the substrate alignment assembly comprises a first shifting unit coupled to the first shifting plate and comprising a first adjustment mechanism; and
wherein turning the first adjustment mechanism causes the first susceptor to shift along the first axis.

16. The semiconductor processing system of claim 13, wherein the substrate alignment assembly comprises a second shifting unit coupled to the second shifting plate and comprising a second adjustment mechanism; and
wherein turning the second adjustment mechanism causes the first susceptor to shift along the second axis.

17. The semiconductor processing system of claim 13, wherein the substrate alignment assembly comprises:
a third shifting plate coupled to the second alignment plate; and
a fourth shifting plate coupled to the third shifting plate,
wherein a third shifting of the third shifting plate causes a third corresponding shifting in the second susceptor along the first axis; and
wherein a fourth shifting of the fourth shifting plate causes a fourth corresponding shifting in the second susceptor along the second axis.

18. The semiconductor processing system of claim 17, wherein the substrate alignment assembly comprises a third shifting unit coupled to the third shifting plate and comprising a third adjustment mechanism; and
wherein turning the third adjustment mechanism causes the second susceptor to shift along the first axis.

19. The semiconductor processing system of claim 17, wherein the substrate alignment assembly comprises a fourth shifting unit coupled to the fourth shifting plate and comprising a fourth adjustment mechanism; and
wherein turning the fourth adjustment mechanism causes the second susceptor to shift along the second axis.

20. The semiconductor processing system of claim 1, wherein the first adjustment or the second adjustment is performed by a human operator or a controller.
